(19) United States
(12) Patent Application Publication
(10) Pub. No.: US 2025/0259912 A1
(43) Pub. Date: Aug. 14, 2025

(54) SEMICONDUCTOR PACKAGE AND METHOD OF FABRICATING THE SAME

(71) Applicant: Samsung Electronics Co., Ltd., Suwon-si (KR)

(72) Inventors: Ki Tae PARK, Suwon-si (KR); Seon Kyu KIM, Suwon-si (KR); Yong Jae SONG, Suwon-si (KR); Chi Wan SONG, Suwon-si (KR); Jae Wook JUNG, Suwon-si (KR); Seung Min BAEK, Suwon-si (KR); Joon Seok OH, Suwon-si (KR)

(21) Appl. No.: 18/810,729

(22) Filed: Aug. 21, 2024

(30) Foreign Application Priority Data
Feb. 13, 2024 (KR) 10-2024-0020397

(51) Int. Cl. H01L 23/48; H01L 21/768; H01L 23/00; H01L 23/522; H01L 25/18; H10B 80/00

(52) U.S. Cl. CPC H01L 23/481; H01L 21/76898; H01L 23/5223; H01L 23/5226; H01L 24/16; H01L 24/32; H01L 24/73; H01L 24/80; H01L 25/18; H01L 2224/16227; H01L 2224/32145; H01L 2224/32225; H01L 2224/73204; H01L 2224/80895; H01L 2224/80896; H01L 2225/06517; H01L 2225/06544; H01L 2225/06555; H01L 2924/1431; H01L 2924/1436; H10B 80/00

(57) ABSTRACT

A semiconductor package that include a MIM structure for capacitance measurement is provided. The semiconductor package includes a package substrate, a first semiconductor chip mounted on the package substrate, and a second semiconductor chip mounted on the package substrate and spaced apart from the first semiconductor chip, wherein the second semiconductor chip includes a buffer die, a first passivation film on the buffer die, a first memory die stacked on the first passivation film, a second passivation film on the first memory die, a second memory die stacked on the second passivation film, first vias in the buffer die, the first passivation film, the first memory die, the second passivation film, and the second memory die, and second vias in the first and second memory dies, respectively, and the second vias are configured to indicate an alignment between the first and second memory dies.

### CROSS-REFERENCE TO RELATED APPLICATIONS

This application claims priority from Korean Patent Application No. 10-2024-0020397 filed on Feb. 13, 2024, in the Korean Intellectual Property Office, and all the benefits accruing therefrom under 35 U.S.C. 119, the contents of which in its entirety are herein incorporated by reference.

### BACKGROUND OF THE INVENTION

### 1. Field

The present disclosure relates to a semiconductor package including a High Bandwidth Memory (HBM) and a method of manufacturing the semiconductor package.

### 2. Description of the Related Art

In the manufacture of semiconductor packages that include HBM, Hybrid Copper Bonding (HCB) can be applied for bonding dies to improve (e.g., optimize) thermal performance and enhance signal stability.

When bonding dies using the HCB method, the metal filled in through silicon vias (TSVs) can serve as electrodes. Therefore, the alignment between the TSVs of an upper die and the TSVs of a lower die can significantly impact the product's performance.

Conventionally, vision sensors have been utilized to detect the alignment between upper and lower dies. However, this type of method has limitations in analyzing dies with stacked structures, and it may be difficult (e.g., nearly impossible) to detect misalignments that are only partially connected.

### SUMMARY OF THE INVENTION

Aspects of the present disclosure provide a semiconductor package and its manufacturing method that include a Metal Insulator Metal (MIM) structure for capacitance measurement.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor package includes: a package substrate; a first semiconductor chip mounted on the package substrate; and a second semiconductor chip mounted on the package substrate and spaced apart from the first semiconductor chip, wherein the second semiconductor chip includes a buffer die, a first passivation film on the buffer die, a first memory die stacked on the first passivation film, a second passivation film on the first memory die, a second memory die stacked on the second passivation film, first vias in the buffer die, the first passivation film, the first memory die, the second passivation film, and the second memory die, and second vias in the first and second memory dies, respectively, and the second vias are configured to indicate an alignment between the first and second memory dies.

According to another aspect of the present disclosure, a method of manufacturing a semiconductor chip, includes: forming a first passivation film on a buffer die; stacking a first memory die on the first passivation film; forming a first via that is in the first passivation film and the first memory die; forming a second via that is in the first memory die; forming a second passivation film on the first memory die; stacking a second memory die on the second passivation film; forming another first via that is in the second passivation film and the second memory die; and forming another second via that is in the second memory die.

According to another aspect of the present disclosure, a semiconductor package includes: a package substrate; a first semiconductor chip mounted on the package substrate; and a second semiconductor chip mounted on the package substrate and spaced apart from the first semiconductor chip, wherein the second semiconductor chip includes a buffer die, a first passivation film on the buffer die, a first memory die stacked on the first passivation film, a second passivation film on the first memory die, a second memory die stacked on the second passivation film, first vias in the buffer die, the first passivation film, the first memory die, the second passivation film, and the second memory die, and second vias in the first and second memory dies, the second passivation film includes a second lower insulating film on the first memory die and a second upper insulating film on the second lower insulating film, and the second vias are in the second upper insulating film and are not in the second lower insulating film, the second vias include a conductive material, and the second passivation film includes an insulating material, the second via in the first memory die is connected to a first capacitor, the second via in the second memory die is connected to a second capacitor, and a capacitance that corresponds to the first and second capacitors corresponds to an alignment between the first and second memory dies.

A semiconductor package, according to some embodiments herein, may include a package substrate. The semiconductor package may include a first semiconductor chip and a second semiconductor chip that are on the package substrate. The second semiconductor chip may include a first memory die. The second semiconductor chip may include a second memory die that is on the first memory die. The second semiconductor chip may include a passivation film that is between the first memory die and the second memory die. The second semiconductor chip may include a first via that is in the first memory die. The second semiconductor chip may include a second via that is in the first memory die. Moreover, the second semiconductor chip may include a third via that is in the second memory die. A lower surface of the third via may overlap an upper surface of the second via. The passivation film may be between the lower surface of the third via and the upper surface of the second via.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view for explaining a semiconductor package according to an embodiment of the present disclosure.

FIG. 2 is a sectional view for explaining the semiconductor package according to an embodiment of the present disclosure.

FIG. 3 is an example cross-sectional view for explaining a second semiconductor chip according to some embodiments of the present disclosure.

FIG. 4 is a partial enlarged cross-sectional view for explaining the second semiconductor chip according to some embodiments of the present disclosure.

FIG. 5 is a cross-sectional view for explaining a second semiconductor chip according to further embodiments of the present disclosure.

FIG. 6 is a schematic view for explaining a system for evaluating the alignment state of a second semiconductor chip according to some embodiments of the present disclosure.

FIG. 7 is a first example cross-sectional view for explaining a method of evaluating the alignment state of a second semiconductor chip according to some embodiments of the present disclosure.

FIG. 8 is a second example cross-sectional view for explaining the method of evaluating the alignment state of a second semiconductor chip according to some embodiments of the present disclosure.

FIG. 9 is a third example diagram for explaining a method of evaluating the alignment state of the second semiconductor chip according to some embodiments of the present disclosure.

FIG. 10 is a fourth example diagram for explaining a method of evaluating the alignment state of a second semiconductor chip according to some embodiments of the present disclosure.

FIG. 11 is a fifth example diagram for explaining the method of evaluating the alignment state of a second semiconductor chip according to some embodiments of the present disclosure.

FIG. 12 is a flowchart for explaining a method of manufacturing a second semiconductor chip according to some embodiments of the present disclosure.

FIGS. 13 through 20 are cross-sectional views for explaining a method of forming first and second vias within a second semiconductor chip according to some embodiments of the present disclosure.

### DETAILED DESCRIPTION

Embodiments of the present disclosure will hereinafter be described with reference to the accompanying drawings. The same reference numerals are used for identical components in the drawings, and redundant explanations for these components are omitted.

The present disclosure relates to a semiconductor package that includes a High Bandwidth Memory (HBM) and a method of manufacturing the semiconductor package. The semiconductor package can bond a plurality of dies using the Hybrid Copper Bonding (HCB) method and may include a Metal Insulator Metal (MIM) structure for the analysis of alignment of stacked dies for capacitance measurement.

The semiconductor package will hereinafter be described first, followed by an explanation of the MIM structure and the method of manufacturing the semiconductor package.

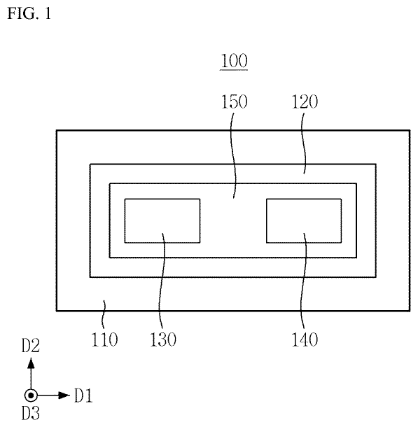

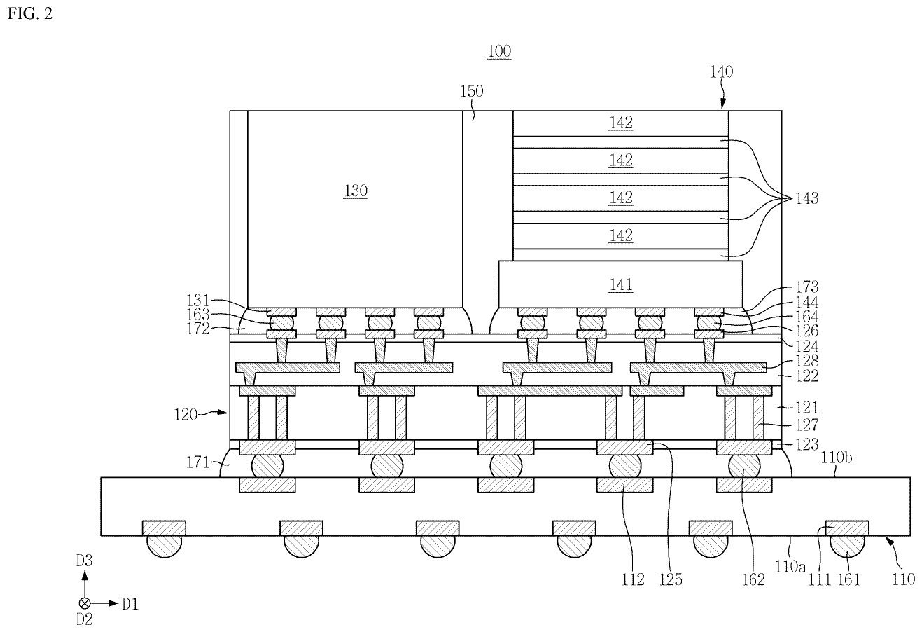

FIG. 1 is a plan view for explaining a semiconductor package according to an embodiment of the present disclosure. FIG. 2 is a sectional view for explaining the semiconductor package according to an embodiment of the present disclosure. FIG. 2 is a sectional view, taken along a first direction D1, of a semiconductor package 100 of FIG. 1.

Referring to FIGS. 1 and 2, the semiconductor package 100 may include a package substrate 110, an interposer structure 120, a first semiconductor chip 130, a second semiconductor chip 140, and a molding member 150.

The first direction D1 and a second direction D2 form a horizontal plane. For example, the first direction D1 may be a front-back direction, and the second direction D2 may be a left-right direction. Alternatively, the first direction D1 may be the left-right direction, and the second direction D2 may be the front-back direction. A third direction D3 forms a three-dimensional (3D) space together with the first and second directions D1 and D2. The third direction D3 is perpendicular to the plane formed by the first and second directions D1 and D2. The third direction D3 may be an up-down (i.e., vertical) direction.

The package substrate 110 may be formed based on (e.g., may comprise) a printed circuit board (PCB), a wafer substrate, a ceramic substrate, a glass substrate, etc. The package substrate 110 may have first and second surfaces 110a and 110b. The first surface 110a may be the bottom surface of the package substrate 110, and the second surface 110b may be the top surface of the package substrate 110.

The package substrate 110 may include first substrate pads 111 and second substrate pads 112. The first substrate pads 111 may be formed on the first surface 110a of the package substrate 110, and the second substrate pads 112 may be formed on the second surface 110b of the package substrate 110. The first substrate pads 111 and the second substrate pads 112 may be exposed on (e.g., not covered by) the first surface 110a and the second surface 110b, respectively, of the package substrate 110. The first substrate pads 111 and the second substrate pads 112 may protrude from the first surface 110a and the second surface 110b, respectively, of the package substrate 110. Alternatively, the first substrate pads 111 and the second substrate pads 112 may be buried in the first surface 110a and the second surface 110b, respectively, of the package substrate 110.

A plurality of first substrate pads 111 and a plurality of second substrate pads 112 may be formed. The same number of first substrate pads 111 and second substrate pads 112 may be formed, but the present disclosure is not limited thereto. In the example of FIG. 2, the number of first substrate pads 111 may be six, and the number of second substrate pads 112 may be five. However, the present disclosure is not limited to this example.

The first substrate pads 111 and the second substrate pads 112 may include a metal material. For example, the first substrate pads 111 and the second substrate pads 112 may include at least one selected from among aluminum (Al), copper (Cu), nickel (Ni), tungsten (W), platinum (Pt), and gold (Au), but the present disclosure is not limited thereto.

The package substrate 110 may further include first solder balls 161, which are connected to the first substrate pads 111. The first substrate pads 111 and the first solder balls 161 may be used to electrically connect the package substrate 110 to a module substrate or system board of an electronic product. The package substrate 110 may be mounted on a module substrate or system board of an electronic product through the first solder balls 161. For example, the package substrate 110 may be provided as a Ball Grid Array (BGA) substrate, but the present disclosure is not limited thereto.

The first solder balls 161 may be provided as solder bumps, but the present disclosure is not limited thereto. The first solder balls 161 may have various shapes such as a land shape, a ball shape, a pin shape, a pillar shape, etc. The number, spacing, and arrangement of the first solder balls 161 are not particularly limited and may vary depending on the design of the semiconductor package 100.

The interposer structure 120 may be mounted on the second surface 110b of the package substrate 110. Although not explicitly labelled in FIGS. 1 and 2, the interposer structure 120 may have first and second surfaces. The first surface of the interposer structure 120 may be the bottom surface of the interposer structure 120, and the second surface of the interposer structure 120 may be the top surface of the interposer structure 120. The first surface of the interposer structure 120 may be adjacent to the package substrate 110, and the second surface of the interposer structure 120 may be adjacent to the first and second semiconductor chips 130 and 140.

The interposer structure 120 may be electrically connected to the first semiconductor chip 130. The interposer structure 120 may be electrically connected to the second semiconductor chip 140. The first and second semiconductor chips 130 and 140 may be electrically connected to the package substrate 110 through the interposer structure 120. The first and second semiconductor chips 130 and 140 may be electrically connected to each other through the interposer structure 120. The interposer structure 120 can reduce/prevent warpage of the semiconductor package 100.

The interposer structure 120 may include an interposer 121, an interlayer insulating layer 122, a first passivation layer 123, a second passivation layer 124, first interposer pads 125, and second interposer pads 126.

The interposer 121 may be provided as a silicon (Si) substrate, but the present disclosure is not limited thereto. Alternatively, the interposer 121 may be provided as a substrate formed of one of an organic material, plastic, and glass.

The interlayer insulating layer 122 may be formed above the interposer 121, but the present disclosure is not limited thereto. Alternatively, the interlayer insulating layer 122 may be formed below the interposer 121. Yet alternatively, the interlayer insulating layer 122 may be formed both above and below the interposer 121.

The interlayer insulating layer 122 may include an insulating material. For example, the interlayer insulating layer 122 may include at least one of silicon oxide, silicon nitride, silicon oxynitride, and a low-k material with a lower dielectric constant than silicon oxide, but the present disclosure is not limited thereto.

The first passivation layer 123 may be formed below the interposer 121. The second passivation layer 124 may be formed above the interlayer insulating layer 122. The interlayer insulating layer 122 and the first passivation layer 123 may be respectively disposed above and below the interposer 121, and the second passivation layer 124 and the interposer 121 may be respectively disposed above and below the interlayer insulating layer 122. The first and second passivation layers 123 and 124 may include silicon nitride, but the present disclosure is not limited thereto. Alternatively, the first and second passivation layers 123 and 124 may be formed of a passivation material, benzocyclobutene (BCB), polybenzoxazole, polyimide, epoxy, silicon oxide, silicon nitride, or a combination thereof.

The first interposer pads 125 may be used to electrically connect the package substrate 110 and the interposer structure 120. The second interposer pads 126 may be used to electrically connect the interposer structure 120 and the first semiconductor chip 130. The second interposer pads 126 may also be used to electrically connect the interposer structure 120 and the second semiconductor chip 140. The second interposer pads 126 may also be used to electrically connect the first and second semiconductor chips 130 and 140 to each other.

The first interposer pads 125 may be formed on the first passivation layer 123, and the second interposer pads 126 may be formed on the second passivation layer 124. The first interposer pads 125 and the second interposer pads 126 may be exposed on (e.g., not covered by) the surface of the first passivation layer 123 and the surface of the second passivation layer 124, respectively. The first interposer pads 125 and the second interposer pads 126 may protrude from the first passivation layer 123 and the second passivation layer 124, respectively. Alternatively, the first interposer pads 125 and the second interposer pads 126 may be buried in the first passivation layer 123 and the second passivation layer 124, respectively.

A plurality of first interposer pads 125 and a plurality of second interposer pads 126 may be formed. The same number of first interposer pads 125 and second substrate pads 112 may be formed, but the present disclosure is not limited thereto. Alternatively, different numbers of first interposer pads 125 and second substrate pads 112 may be formed. In the example of FIG. 2, the number of the first interposer pads 125 is five, and the number of the second interposer pads 126 is eight. However, the present disclosure is not limited to this example.

The first interposer pads 125 and the second interposer pads 126 may include a metal material. For example, the first interposer pads 125 and the second interposer pads 126 may include at least one selected from Al, Cu, Ni, W, Pt, and Au, but the present disclosure is not limited thereto.

In some embodiments, the interposer structure 120 may not include the first and second passivation layers 123 and 124. In this case, the first interposer pads 125 may be formed on the interposer 121, and the second interposer pads 126 may be formed on the interlayer insulating layer 122. The first interposer pads 125 may be exposed from (e.g., not covered by) the surface of the interposer 121. The surface from which the first interposer pads 125 are exposed may be the bottom surface of the interposer 121 that is adjacent to the package substrate 110. The second interposer pads 126 may be exposed from (e.g., not covered by) the surface of the interlayer insulating layer 122. The surface from which the second interposer pads 126 are exposed may be the top surface of the interlayer insulating layer 122 that is adjacent to the first and second semiconductor chips 130 and 140.

The interposer structure 120 may include through electrodes 127 and redistribution patterns 128 to electrically connect the first interposer pads 125 and the second interposer pads 126.

Vias may be formed through the interposer 121 in the third direction D3. The vias may be Through Silicon Vias (TSVs). The through electrodes 127 may be formed in (e.g., by filling) the vias.

The through electrodes 127 may have a pillar shape and include a barrier film on their outside and a buried conductive layer on their inside. The barrier film may include at least one material selected from among titanium (Ti), titanium nitride (TiN), tantalum (Ta), tantalum nitride (TaN), ruthenium (Ru), cobalt (Co), manganese (Mn), tungsten nitride (WN), Ni, and nickel boron (NiB). The buried conductive layer may include at least one material selected from among a Cu alloy, W, a W alloy, Ni, Ru, and Co. Here, the Cu alloy may be selected from among Cu, CuSn, CuMg, CuNi, CuZn, CuPd, CuAu, CuRe, and CuW.

The redistribution patterns 128 may be formed within the interlayer insulating layer 122. Alternatively, the redistribution patterns 128 may be formed within both the interposer 121 and the interlayer insulating layer 122. The redistribution patterns 128 may be formed as multilayers. Alternatively, the redistribution patterns 129 may be formed as single layers. The redistribution patterns 128 may include a metal material such as Cu or Al, but the present disclosure is not limited thereto.

The through electrodes 127 and the redistribution patterns 128 may be electrically connected. The through electrodes 127 may be electrically connected to the first interposer pads 125. The redistribution patterns 128 may be electrically connected to the second interposer pads 126. The through electrodes 127 may be electrically connected to the second interposer pads 126 through the redistribution patterns 128. The redistribution patterns 128 may be electrically connected to the first interposer pads 125 through the through electrodes 127.

Second solder balls 162 may be provided to electrically connect the package substrate 110 and the interposer structure 120. The second solder balls 162 may be disposed between the package substrate 110 and the interposer structure 120. The second solder balls 162 may be connected to both the second substrate pads 112 and the first interposer pads 125. The second solder balls 162 may be included in the package substrate 110. Alternatively, the second solder balls 162 may be included in the interposer structure 120.

The second solder balls 162 may be provided as solder bumps containing a low-melting-point metal. For example, the second solder balls 162 may be solder bumps containing tin (Sn) or an Sn alloy, but the present disclosure is not limited thereto. The second solder balls 162 may have various shapes such as a land shape, a ball shape, a pin shape, a pillar shape, etc.

The second solder balls 162 may be formed as single layers. Alternatively, the second solder balls 162 may be formed as multilayers. When formed as single layers, the second solder balls 162 may include tin-silver (Sn—Ag) solder or Cu. When formed as multilayers, the second solder balls 162 may include Cu filler and solder. However, the present disclosure is not limited to these examples. The number, spacing, and arrangement of second solder balls 162 are not particularly limited and may vary depending on the design of the semiconductor package 100.

A first underfill 171 may fill the empty space between the package substrate 110 and the interposer structure 120. The first underfill 171 may cover the second solder balls 162. The first underfill 171 may include one of an epoxy-based resin, BCB, or polyimide. Alternatively, the first underfill 171 may include an insulating polymeric material such as an Epoxy Molding Compound (EMC), but the present disclosure is not limited thereto.

The first and second semiconductor chips 130 and 140 may be mounted on the interposer structure 120. The first and second semiconductor chips 130 and 140 may be stacked on the package substrate 110 through the interposer structure 120. The first and second semiconductor chips 130 and 140 may be spaced apart from each other.

The first semiconductor chip 130 may consist of one or more logic chips. Although not explicitly illustrated in FIG. 2, the first semiconductor chip 130 may include multiple logic devices. The first semiconductor chip 130 may include logic circuits such as AND gates, OR gates, NOT gates, flip-flops, etc. The first semiconductor chip 130 may be provided to include devices for performing signal processing such as analog signal processing, analog-to-digital conversion, control, etc.

The first semiconductor chip 130 may be provided as a central processing unit (CPU), a graphics processing unit (GPU), a field programmable gate array (FPGA), an application-specific integrated circuit (ASIC), a microprocessor, a microcontroller, a digital signal processor, an application processor, a network processor, an encryption processor, a chipset, a video codec, an audio codec, a system-on-chip (SoC), etc., but the present disclosure is not limited thereto.

The first semiconductor chip 130 may include first chip pads 131. The first chip pads 131 may be used to electrically connect the interposer structure 120 and the first semiconductor chip 130. The first chip pads 131 may also be used to electrically connect the first and second semiconductor chips 130 and 140. The first chip pads 131 may be exposed from (e.g., not covered by) the bottom surface of the first semiconductor chip 130.

The first chip pads 131 may include a metal material. For example, the first chip pads 131 may include a metal such as Al, Cu, Ni, W, Pt, or Au, but the present disclosure is not limited thereto.

The second semiconductor chip 140 may be provided as a memory chip. For example, the second semiconductor chip 140 may be provided as a volatile memory. Alternatively, the second semiconductor chip 140 may be provided as a nonvolatile memory. When provided as a volatile memory, the second semiconductor chip 140 may be a dynamic random-access memory (DRAM), a static random-access memory (SRAM), or a thyristor random-access memory (TRAM). When provided as a nonvolatile memory, the second semiconductor chip 140 may be a flash memory, a phase change random-access memory (PRAM), a magnetic random-access memory (MRAM), a ferroelectric random-access memory (FeRAM), a resistive random-access memory (RRAM), or a spin transfer torque-MRAM (STT-MRAM).

The second semiconductor chip 140 may be configured as a memory chip set including a plurality of memory chips that can merge data with one another. The second semiconductor chip 140 may be provided as a stacked memory such as an HBM.

The second semiconductor chip 140 may include a buffer die 141, memory dies 142, and passivation films 143. The buffer die 141, which is disposed at the bottom of the second semiconductor chip 140, may serve as a circuit. A plurality of memory dies 142 and a plurality of passivation films 143 may be provided. The memory dies 142 may be sequentially stacked in the third direction D3 on the buffer die 141. Each of the passivation films 143 may be formed between two adjacent memory dies 142 in the third direction D3. The same number of memory dies 142 and passivation films 143 may be provided. In the example of FIG. 2, four memory dies 142 and four passivation films 143 may be provided, but the number of memory dies 142 and passivation films 143 are not limited thereto. Although not explicitly illustrated in FIG. 2, the buffer die 141 and the memory dies 142 may be electrically connected through TSVs.

The second semiconductor chip 140 may include second chip pads 144. The second chip pads 144 may be used to electrically connect the interposer structure 120 and the second semiconductor chip 140. The second chip pads 144 may also be used to electrically connect the first and second semiconductor chips 130 and 140. The second chip pads 144 may be exposed from (e.g., not covered by) the bottom surface of the second semiconductor chip 140.

The second chip pads 144 may include a metal material. For example, the second chip pads 144 may include a metal such as Al, Cu, Ni, W, Pt, or Au, but the present disclosure is not limited thereto.

First bumps 163 may be provided to electrically connect the interposer structure 120 and the first semiconductor chip 130. A plurality of first bumps 163 may be provided. The first bumps 163 may be disposed between the interposer structure 120 and the first semiconductor chip 130. The first bumps 163 may be connected to both the second interposer pads 126 and the first chip pads 131. The first bumps 163 may be included in the interposer structure 120. Alternatively, the first bumps 163 may be included in the first semiconductor chip 130.

Second bumps 164 may be provided to electrically connect the interposer structure 120 and the second semiconductor chip 140. A plurality of second bumps 164 may be provided. The second bumps 164 may be disposed between the interposer structure 120 and the second semiconductor chip 140. The second bumps 164 may be connected to both the second interposer pads 126 and the second chip pads 144. The second bumps 164 may be included in the interposer structure 120. Alternatively, the second bumps 164 may be included in the second semiconductor chip 140.

The first bumps 163 and the second bumps 164 may be provided as solder bumps. For example, the first bumps 163 and the second bumps 164 may be provided as solder bumps containing a low-melting-point metal, such as Sn or an Sn alloy, but the present disclosure is not limited thereto. The first bumps 163 and the second bumps 164 may have various shapes, such as a land shape, a ball shape, a pin shape, a pillar shape, etc. The first bumps 163 and the second bumps 164 may include Under Bump Metallurgy (UBM).

The first bumps 163 and the second bumps 164 may be formed as single layers.

Alternatively, the first bumps 163 and the second bumps 164 may be formed as multilayers. When formed as single layers, the first bumps 163 and the second bumps 164 may include Sn—Ag solder or Cu. When formed as multilayers, the first bumps 163 and the second bumps 164 may include Cu filler and solder. However, the present disclosure is not limited to these examples. The numbers, spacings, and arrangements of the first bumps 163 and second bumps 164 are not particularly limited and may vary depending on the design of the semiconductor package 100.

A second underfill 172 may fill the empty space between the interposer structure 120 and the first semiconductor chip 130. The second underfill 172 may cover the first bumps 163. A third underfill 173 may fill the empty space between the interposer structure 120 and the second semiconductor chip 140. The third underfill 173 may cover the second bumps 164.

The second and third underfills 172 and 173 may include one of an epoxy-based resin, BCB, and polyimide. Alternatively, the second and third underfills 172 and 173 may include an insulating polymeric material such as an EMC. However, the present disclosure is not limited to these examples.

The molding member 150 may be on (e.g., may cover) the sides (e.g., sidewalls) of the first and second semiconductor chips 130 and 140. The molding member 150 may not cover the top surfaces of the first and second semiconductor chips 130 and 140. Rather, a top surface of the molding member 150 may be coplanar with the top surfaces of the first and second semiconductor chips 130 and 140. The top surfaces of the first and second semiconductor chips 130 and 140 may be exposed externally. If the second semiconductor chip 140 includes the buffer die 141 and the memory dies 142, the molding member 150 may be on (e.g., may cover) the top surface of the buffer die 141. The molding member 150 may also cover the sides (e.g., side surfaces) of the second and third underfills 172 and 173.

The molding member 150 may include an insulating polymer material. For example, the molding member 150 may include an EMC. Alternatively, the molding member 150 may include an epoxy-based resin, BCB, or polyimide. Yet alternatively, the molding member 150 may include silica filler or flux. However, the present disclosure is not limited to these examples.

Although not explicitly illustrated in FIG. 2, the semiconductor package 100 may further include a stiffener. The stiffener may be formed on the package substrate 110. The stiffener may be formed along the outermost edges of the package substrate 110. The stiffener can reduce/prevent warpage. The molding member 150 may be attached to the package substrate 110. For example, the stiffener may be attached to the package substrate 110 using a thermally conductive adhesive tape, grease, or adhesive.

The stiffener may be spaced apart from the interposer structure 120 and the first and second semiconductor chips 130 and 140. The stiffener may not contact the first, second, and third underfills 171, 172, and 173. The empty space between the interposer structure 120, the semiconductor chips 130 and 140, the underfills 171, 172, and 173, and the stiffener may be filled with the molding member 150.

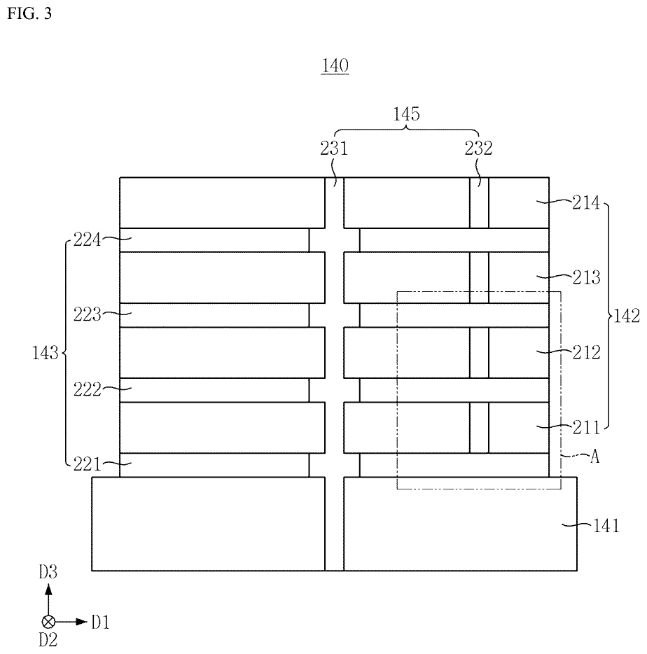

The semiconductor package 100 may include the first and second semiconductor chips 130 and 140. In some embodiments, the first semiconductor chip 130 may be provided as an ASIC, and the second semiconductor chip 140 may be provided as an HBM. As previously mentioned, the second semiconductor chip 140 may include the buffer die 141, the memory dies 142, and the passivation films 143. FIG. 3 is an example cross-sectional view for explaining a second semiconductor chip 140 according to some embodiments of the present disclosure. FIG. 3 is a cross-sectional view, taken along the first direction D1, of the second semiconductor chip 140 of FIG. 1. According to some embodiments, the second semiconductor chip 140 shown in FIG. 3 may be used in the semiconductor package 100 of FIG. 2.

The memory dies 142 may be formed to include a semiconductor material. For example, the memory dies 142 may be formed of an Si material. A plurality of memory dies 142 may be provided. For example, the memory dies 142 may include a first memory die 211, a second memory die 212, a third memory die 213, and a fourth memory die 214. The memory dies 142 may be sequentially stacked on the buffer die 141. The first memory die 211 may be stacked on the buffer die 141. The second memory die 212 may be stacked on the first memory die 211. The third memory die 213 may be stacked on the second memory die 212. The fourth memory die 214 may be stacked on the third memory die 213.

The passivation films 143 may be formed to include a dielectric material. For example, the passivation films 143 may be formed of an XO material, an XN material, or an XCN material. Here, X may be Si, but the present disclosure is not limited thereto. A plurality of passivation films 143 may be provided. For example, the passivation films 143 may include a first passivation film 221, a second passivation film 222, a third passivation film 223, and a fourth passivation film 224. Each of the passivation films 143 may be formed between two adjacent dies in the third direction D3. The first passivation film 221 may be formed between the buffer die 141 and the first memory die 211. The second passivation film 222 may be formed between the first and second memory dies 211 and 212. The third passivation film 223 may be formed between the second and third memory dies 212 and 213. The fourth passivation film 224 may be formed between the third and fourth memory dies 213 and 214.

The buffer die 141 and the four memory dies, i.e., the first, second, third, and fourth dies 211, 212, 213, and 214, may be bonded with the four passivation films, i.e., the first, second, third, and fourth passivation films 221, 222, 223, and 224 therebetween. The buffer die 141 and the first, second, third, and fourth dies 211, 212, 213, and 214 may be bonded using the HCB method.

The second semiconductor chip 140 may include vias 145. The vias 145 may be formed having the third direction D3 as its length direction. The vias 145 may be formed perpendicularly to the stacked structure including the buffer die 141, the memory dies 142, and the passivation films 143. A plurality of vias 145 may be provided. For example, the vias 145 may include first vias 231 and second vias 232.

A single first via 231 and a single second via 232 may be provided. Alternatively, a plurality of first vias 231 and a plurality of second vias 232 may be provided. The first vias 231 and the second vias 232 may include (e.g., may be filled with) a conductive (e.g., metal) material. For example, the first vias 231 and the second vias 232 may be filled with Cu. The first vias 231 and the second vias 232 may be provided as TSVs.

The first vias 231 may be in (e.g., may penetrate) the entire stacked structure within the second semiconductor chip 140. The first vias 231 may be in (e.g., may penetrate) the buffer die 141, the first, second, third, and fourth dies 211, 212, 213, and 214, and the first, second, third, and fourth passivation films 221, 222, 223, and 224. The first vias 231 may each serve as an electrode. The first vias 231 may be used for signal transmission. The first vias 231 may be physically and electrically connected to each other by a conductive material (e.g., metal), and may collectively be referred to herein as a “via structure,” which may extend continuously from the buffer die 141 upward (in the third direction D3) into the fourth die 214 (and thus through the first, second, and third dies 211-213 and the first, second, third, and fourth passivation films 221-224).

First portions of the first vias 231 in (e.g., within) the buffer die 141 and the first, second, third, and fourth memory dies 211, 212, 213, and 214 may be filled with a metal layer. Second portions of the first vias 231 in (e.g., within) the first, second, third, and fourth passivation films 221, 222, 223, and 224 may be filled with a metal pad layer. The second portions of the first vias 231 in (e.g., within) the first, second, third, and fourth passivation films 221, 222, 223, and 224 may have a larger width than the first portions of the first vias 231 in (e.g., within) the buffer die 141 and the first, second, third, and fourth memory dies 211, 212, 213, and 214 in the first direction D1. Moreover, the second portions of the first vias 231 may have a larger width than the second vias 232 in the first direction D1. The metal pad layer may be wider than the metal layer in the first direction D1.

The second vias 232 may be in (e.g., may penetrate a portion of) the stacked structure within the second semiconductor chip 140. The second vias 232 may be in (e.g., may penetrate) the first, second, third, and fourth memory dies 211, 212, 213, and 214. The second vias 232 may not be in (e.g., may not penetrate) the first, second, third, and fourth passivation films 221, 222, 223, and 224. The second vias 232 may or may not be in (e.g., penetrate) the buffer die 141. The second vias 232 may indicate/define (e.g., may be used to analyze) the alignment of the first, second, third, and fourth memory dies 211, 212, 213, and 214, which are sequentially stacked. The second vias 232 may also be used for capacitance measurement.

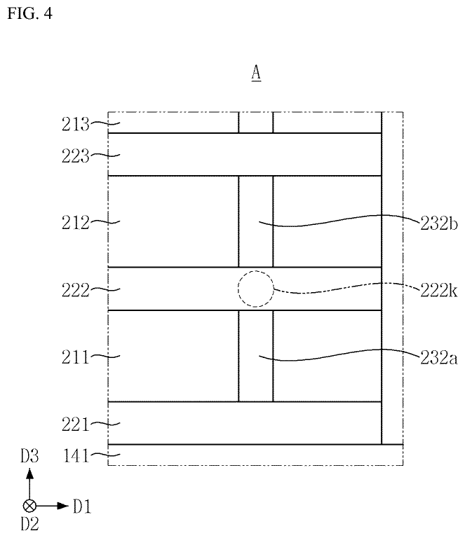

The memory dies 142 with the second vias 232 formed therein and the passivation films 143 without the second vias 232 may create an MIM structure. FIG. 4 is a partial enlarged cross-sectional view for explaining the second semiconductor chip according to some embodiments of the present disclosure. FIG. 4 is an enlarged cross-sectional view of part A of FIG. 3.

Referring to the example of FIG. 4, the first memory die 211, the second memory die 212, and the second passivation film 222 may form an MIM structure. A second via 232a within the first memory die 211 may be filled with a metal. A second via 232b within the second memory die 212 may be filled with a metal. A k-th portion 222k of the second passivation film 222 between (in the third direction D3) the second vias 232a and 232b may not be filled with a metal. The second vias 232a and 232b and the k-th portion 222k of the second passivation film 222 may form an MIM structure, and the MIM structure may be used for capacitance measurement. For ease of distinguishing between the second vias 232a and 232b, the via 232a may be referred to herein as “a second via” and the via 232b may be referred to herein as “a third via.”

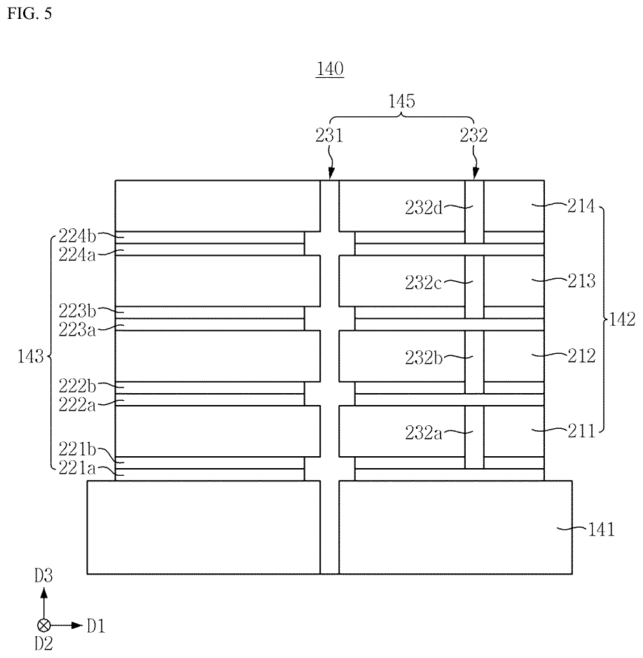

The passivation films 143 may be formed as multilayers. For example, each of the passivation films 143 may consist of two insulating layers. FIG. 5 is a cross-sectional view for explaining a second semiconductor chip 140 according to further embodiments of the present disclosure. FIG. 5 is another example cross-sectional view, taken along the first direction D1, of the second semiconductor chip 140 of FIG. 1. According to some embodiments, the second semiconductor chip 140 shown in FIG. 5 may be used in the semiconductor package 100 of FIG. 2.

The passivation films 143 may include a first passivation film 221, a second passivation film 222, a third passivation film 223, and a fourth passivation film 224. Each of the first, second, third, and fourth passivation films 221, 222, 223, and 224 may include two insulating films. The first passivation film 221 may include a first lower insulating film 221a and a first upper insulating film 221b, which are stacked in the third direction D3. The second passivation film 222 may include a second lower insulating film 222a and a second upper insulating film 222b, which are stacked in the third direction D3. The third passivation film 223 may include a third lower insulating film 223a and a third upper insulating film 223b, which are stacked in the third direction D3. The fourth passivation film 224 may include a fourth lower insulating film 224a and a fourth upper insulating film 224b, which are stacked in the third direction D3. The passivation films 143 may include the first lower insulating film 221a, the first upper insulating film 221b, the second lower insulating film 222a, the second upper insulating film 222b, the third lower insulating film 223a, the third upper insulating film 223b, the fourth lower insulating film 224a, and the fourth upper insulating film 224b.

Each of the first, second, third, and fourth lower insulating films 221a, 222a, 223a, 224a may be formed to include a first dielectric material. Each of the first, second, third, and fourth upper insulating films 221b, 222b, 223b, and 224b may be formed to include a second dielectric material. The first and second dielectric materials may differ from each other. The second dielectric material may offer better bonding performance than the first dielectric material. The second dielectric material may have a lower dielectric constant than the first dielectric material. For example, the first dielectric material may be an XO (where O is oxygen) or XN (where N is nitrogen) material, and the second dielectric material may be an XCN (where C is carbon) material. Here, X may be Si, but the present disclosure is not limited thereto. Accordingly, the first dielectric material may include a first element and a second element that is different from the first element, and second dielectric material may include a third element (and/or the first and/or second elements) that is different from the first and second elements.

When the passivation films 143 consist of lower insulating films and upper insulating films, the second vias 232 may be in (e.g., may penetrate) the upper insulating films but may not be in (e.g., may not penetrate) the lower insulating films. The second via 232a within the first memory die 211 may penetrate the first upper insulating film 221b. The second via 232a within the first memory die 211 may not penetrate the first lower insulating film 221a. The second via 232b within the second memory die 212 may penetrate the second upper insulating film 222b. The second via 232b within the second memory die 212 may not penetrate the second lower insulating film 222a. The second via 232c within the third memory die 213 may penetrate the third upper insulating film 223b. The second via 232c within the third memory die 213 may not penetrate the third lower insulating film 223a. The second via 232d within the fourth memory die 214 may penetrate the fourth upper insulating film 224b. The second via 232d within the fourth memory die 214 may not penetrate the fourth lower insulating film 224a.

Referring to FIG. 5, when the first, second, third, and fourth passivation films 221, 222, 223, and 224 include the first, second, third, and fourth lower insulating films 221a, 222a, 223a, and 224a, respectively, and the first, second, third, and fourth upper insulating films 221b, 222b, 223b, and 224b, respectively, portions of the first vias 231 within the first, second, third, and fourth lower insulating films 221a, 222a, 223a, and 224a and the first, second, third, and fourth upper insulating films 221b, 222b, 223b, and 224b may have a larger width than portions of the first vias 231 within the buffer die 141 and the first, second, third, and fourth memory dies 211, 212, 213, and 214 in the first direction D1. The metal pad layer filled within the former first vias 231 may be wider in the first direction D1 than the metal layer filled in the latter first vias 231.

Alternatively, although not explicitly illustrated in FIG. 5, when the first, second, third, and fourth passivation films 221, 222, 223, and 224 include the first, second, third, and fourth lower insulating films 221a, 222a, 223a, and 224a, respectively, and the first, second, third, and fourth upper insulating films 221b, 222b, 223b, and 224b, respectively, portions of the first vias 231 within the first, second, third, and fourth lower insulating films 221a, 222a, 223a, and 224a may have a larger width than portions of the first vias 231 within the buffer die 141, the first, second, third, and fourth memory dies 211, 212, 213, and 214, and the first, second, third, and fourth upper insulating films 221b, 222b, 223b, and 224b in the first direction D1. The metal pad layer filled within the former first vias 231 may be wider than the metal layer filled within the latter first vias 231 in the first direction D1.

A system and method for evaluating the alignment state of a second semiconductor chip 140 including a plurality of memory dies will hereinafter be described, taking the second semiconductor chip 140 of FIG. 5 as an example. However, the method and system for evaluating the alignment state of a second semiconductor chip 140 may also be applicable to the second semiconductor chip 140 of FIG. 3.

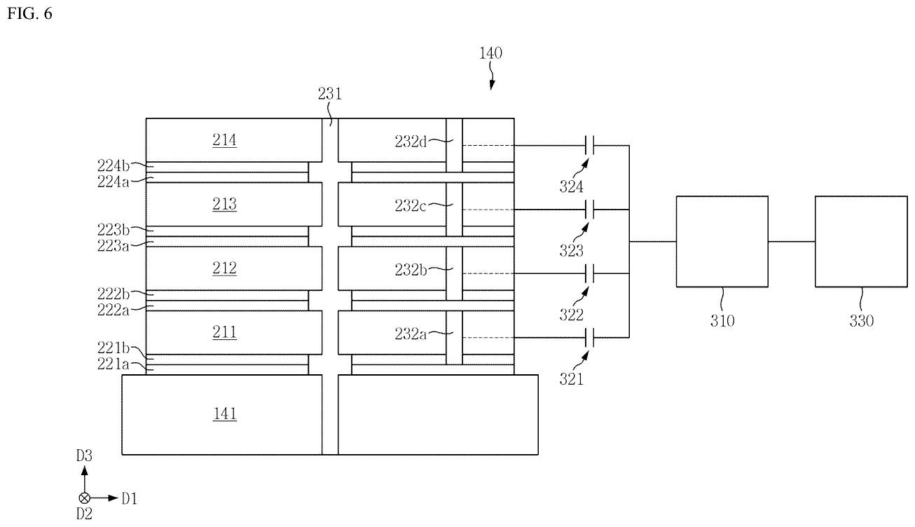

FIG. 6 is a schematic view for explaining a system for evaluating the alignment state of a second semiconductor chip according to some embodiments of the present disclosure. Referring to FIG. 6, a measuring device 310 may be electrically connected to the second vias 232a, 232b, 232c, and 232d within the first, second, third, and fourth memory dies 211, 212, 213, and 214, respectively. The measuring device 310 may be electrically connected to the second via 232a within the first memory die 211. The measuring device 310 may also be electrically connected to the second via 232b within the second memory die 212. The measuring device 310 may also be electrically connected to the second via 232c within the third memory die 213. The measuring device 310 may be electrically connected to the second via 232d within the fourth memory die 214.

Capacitors may be provided at the connections (e.g., junctions/interfaces) between the measuring device 310 and the second vias 232a, 232b, 232c, and 232d within the first, second, third, and fourth memory dies 211, 212, 213, and 214. A first capacitor 321 may be provided at the connection between the measuring device 310 and the second via 232a within the first memory die 211. A second capacitor 322 may be provided at the connection between the measuring device 310 and the second via 232b within the second memory die 212. A third capacitor 323 may be provided at the connection between the measuring device 310 and the second via 232c within the third memory die 213. A fourth capacitor 324 may be provided at the connection between the measuring device 310 and the second via 232d within the fourth memory die 214.

The measuring device 310 may measure capacitance using the capacitors installed at the connections to the second vias 232a, 232b, 232c, and 232d in (e.g., within) the first, second, third, and fourth memory dies 211, 212, 213, and 214. The measuring device 310 may measure capacitance using two capacitors from among the first, second, third, and fourth capacitors 321, 322, 323, and 324. The measuring device 310 may measure capacitance using two capacitors connected to a pair of adjacent second vias. For example, the measuring device 310 may measure capacitance using the first and second capacitors 321 and 322, but the present disclosure is not limited thereto. Alternatively, the measuring device 310 may measure capacitance using two capacitors connected to two second vias that are not adjacent to each other. For example, the measuring device 310 may measure capacitance using the first and fourth capacitors 321 and 324. The measuring device 310 may also measure capacitance using three or more capacitors selected from among the first, second, third, and fourth capacitors 321, 322, 323, and 324.

The measuring device 310 may measure capacitance using the following equation:

$$C = {ε}_{0} * {ε}_{r} * ( n - 1 ) A / d$$

where C denotes capacitance, ϵ₀ denotes vacuum permittivity, & denotes relative permittivity, n denotes the number of electrodes, A denotes the area of the electrodes, and d denotes the distance between two adjacent electrodes in the third direction D3. The number n of electrodes may correspond to the number of second vias 232 formed in each of the memory dies 142. Alternatively, the number n of electrodes may correspond to the number of capacitors. The area A of the electrodes may correspond to the area of the second vias 232. The area A of the electrodes may correspond to the cross-sectional area obtained by cutting the second vias 232 in the first direction D1. The distance d may correspond to the thickness of the passivation films 143, formed between every two (i.e., each pair of) adjacent memory dies. Accordingly, the capacitance C may be a capacitance defined by (e.g., corresponding to, based on) two or more of the second vias 232.

A control device 330 may assess the alignment state of the second semiconductor chip 140 based on capacitance. The control device 330 may evaluate the alignment state of a plurality of memory dies 142 within the second semiconductor chip 140. The control device 330 may determine whether the memory dies 142 are in a normal alignment state or a misalignment state.

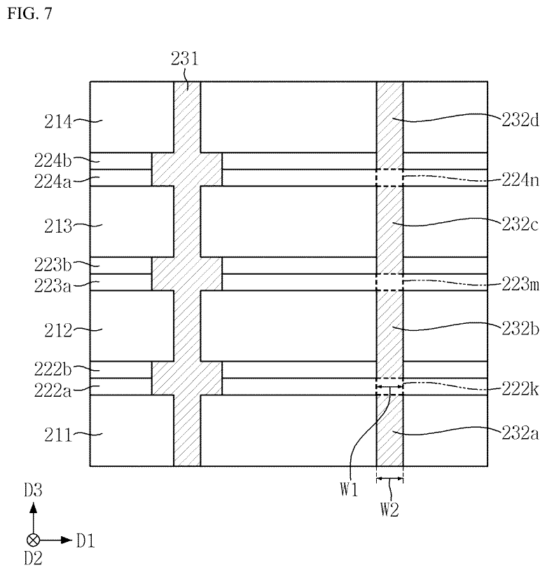

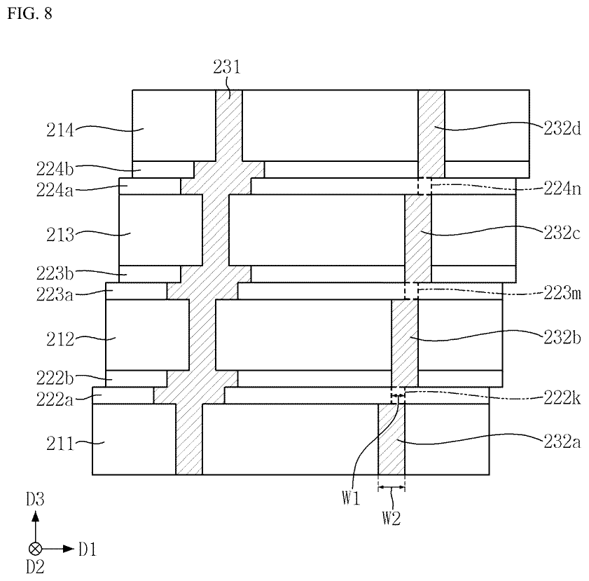

For example, the control device 330 may determine that the first, second, third, and fourth memory dies 211, 212, 213, and 214 are in the normal alignment state if they are aligned as illustrated in FIG. 7. Conversely, the control device may determine that the first, second, third, and fourth memory dies 211, 212, 213, and 214 are in the misalignment state if they are aligned as illustrated in FIG. 8. FIG. 7 is a first example cross-sectional view for explaining a method of evaluating the alignment state of a second semiconductor chip according to some embodiments of the present disclosure. FIG. 8 is a second example cross-sectional view for explaining the method of evaluating the alignment state of a second semiconductor chip according to some embodiments of the present disclosure.

Once the measuring device 310 measures capacitance, the control device 330 may use measurement values from the measurement to assess the alignment of the memory dies 142 within the second semiconductor chip 140. The control device 330 may assess alignment by comparing the measurement values with a reference value. The control device 330 may determine whether the memory dies 142 are in the normal alignment state or the misalignment state based on whether the measurement values match the reference value. Alternatively, the control device 330 may calculate the differences between the measurement values and the reference value and may determine whether the memory dies 142 are in the normal alignment state or the misalignment state based on whether the calculated differences fall within an acceptable (e.g., predetermined) range.

In the former case, the control device 330 may determine that the memory dies 142 are in the normal alignment state if the measurement values match the reference value, and determine that the memory dies 142 are in the misalignment state if the measurement values do not match the reference value. In the latter case, the control device 330 may determine that the memory dies 142 are in the normal alignment state if the differences between the measurement values and the reference value are within the acceptable range, and determine that the memory dies 142 are in the misalignment state if the differences between the measurement values and the reference value exceeds the acceptable range. Accordingly, a measured capacitance value that is based on two or more second vias 232 may correspond to (e.g., may indicate) whether the memory dies 142 are aligned or misaligned.

Referring to FIG. 7, when the first, second, third, and fourth memory dies 211, 212, 213, and 214 are properly aligned, the gaps between every two (i.e., each pair of) adjacent second vias 232 within the passivation films 143 may have the same area (e.g., the same width in the first direction D1) as the second vias 232. For example, an area (e.g., a width) W1 of the k-th portion 222k of the second passivation film 222 may have the same area as an area (e.g., a width) W2 of the second via 232a within the first memory die 211 (i.e., W1=W2). The value of the width W1 indicates the degree to which the second via 232b overlaps the second via 232a in the third direction D3. Accordingly, when W1=W2, an entirety of a lower surface of the second via 232b overlaps an entirety of an upper surface of the second via 232a in the third direction D3, and the second vias 232a, 232b are thus completely aligned with each other. Also, the k-th portion 222k of the second passivation film 222 may have the same area as the second via 232b within the second memory die 212. Similarly, an m-th portion 223m of the third passivation film 223 may have the same area as the second via 232b within the second memory die 212. Also, the m-th portion 223m of the third passivation film 223 may have the same area as the second via 232c within the third memory die 213. Similarly, an n-th portion 224n of the fourth passivation film 224 may have the same area as the second via 232c within the third memory die 213. Also, the n-th portion 224n of the fourth passivation film 224 may have the same area as the second via 232d within the fourth memory die 214.

If the k-th portion 222k of the second passivation film 222, the m-th portion 223m of the third passivation film 223, and the n-th portion 224n of the fourth passivation film 224 have the same area as the second vias 232a, 232b, 232c, and 232d within the first, second, third, and fourth memory dies 211, 212, 213, and 214, the capacitance may not change. Then, the measurement values from the measuring device 310 may be the same as the reference value, or even if there are discrepancies or differences between the measurement values and the reference value, the discrepancies or differences may not exceed the acceptable range.

Conversely, referring to FIG. 8, when the first, second, third, and fourth memory dies 211, 212, 213, and 214 are abnormally aligned or misaligned, the gaps between every two (i.e., each pair of) adjacent second vias 232 within the passivation films 143 may not have the same area (e.g., width) as the second vias 232. For example, the area (e.g., width) W1 of the k-th portion 222k of the second passivation film 222 may not be the same as the area (e.g., width) W2 of the second via 232a within the first memory die 211 (i.e., W1/W2). Specifically, the k-th portion 222k of the second passivation film 222 may have a smaller area (e.g., a narrower width) than the second via 232a within the first memory die 211 (i.e., W1<W2). Also, the k-th portion 222k of the second passivation film 222 may not have the same area as the second via 232b within the second memory die 212. Specifically, the k-th portion 222k of the second passivation film 222 may have a smaller area (e.g., a narrower width) than the second via 232b within the second memory die 212. Similarly, the m-th portion 223m of the third passivation film 223 may not have the same area as the second via 232b within the second memory die 212. Specifically, the m-th portion 223m of the third passivation film 223 may have a smaller area (e.g., a narrower width) than the second via 232b within the second memory die 212. Also, the m-th portion 223m of the third passivation film 223 may not have the same area as the second via 232c within the third memory die 213. Specifically, the m-th portion 223m of the third passivation film 223 may have a smaller area (e.g., a narrower width) than the second via 232c within the third memory die 213. Similarly, the n-th portion 224n of the fourth passivation film 224 may not have the same area as the second via 232c within the third memory die 213. Specifically, the n-th portion 224n of the fourth passivation film 224 may have a smaller area (e.g., a narrower width) than the second via 232c within the third memory die 213. Also, the n-th portion 224n of the fourth passivation film 224 may not have the same area as the second via 232d within the fourth memory die 214. Specifically, the n-th portion 224n of the fourth passivation film 224 may have a smaller area (e.g., a narrower width) than the second via 232d within the fourth memory die 214.

If the k-th portion 222k of the second passivation film 222, the m-th portion 223m of the third passivation film 223, and the n-th portion 224n of the fourth passivation film 224 do not have the same area (e.g., do not have the same width) as the second vias 232a, 232b, 232c, and 232d within the first, second, third, and fourth memory dies 211, 212, 213, and 214, the capacitance may change due to a reduced amount of overlap by the second vias 232a, 232b, 232c, and 232d with each other in the third direction D3. Specifically, if the k-th portion 222k of the second passivation film 222, the m-th portion 223m of the third passivation film 223, and the n-th portion 224n of the fourth passivation film 224 have a smaller area (e.g., a narrower width) than the second vias 232a, 232b, 232c, and 232d within the first, second, third, and fourth memory dies 211, 212, 213, and 214, the capacitance may decrease. As the capacitance decreases, the measurement values from the measurement device 310 may not be the same as the reference value. Accordingly, the differences between the measurement values and the reference value may exceed the acceptable range.

The control device 330 may evaluate the alignment state of the memory dies 142 within the second semiconductor chip 140 based on the results of the comparison between the measurement values and the reference value. The control device 330 may assess the alignment state between the first and second memory dies 211 and 212, generating a first comparison result. The control device 330 may assess the alignment state between the second and third memory dies 212 and 213, generating a second comparison result. The control device 330 may assess the alignment state between the third and fourth memory dies 213 and 214, generating a third comparison result. The control device 330 may determine whether the first, second, and third comparison results all indicate that the memory dies 142 are properly aligned. If all the first, second, and third comparison results indicate that the memory dies 142 are in the normal alignment state, the control device 330 may evaluate the second semiconductor chip 140 as properly aligned. If any of the first, second, and third comparison results indicates abnormal alignment or misalignment, the control device 330 may evaluate the second semiconductor chip 140 as abnormally aligned or misaligned.

The control device 330 may quantitatively assess the alignment state of the memory dies 142 based on the alignment matching between upper dies and lower dies. The control device 330 may evaluate the alignment state between the memory dies 142 in various axial directions. For example, the control device 330 may assess the alignment matching in an X-axis direction (e.g., the first direction D1) between the second vias 232a and 232b within the first and second memory dies 211 and 212. Similarly, the control device 330 may evaluate the alignment matching in a Y-axis direction (e.g., the second direction D2) between the second vias 232a and 232b within the first and second memory dies 211 and 212. Additionally, the control device 330 may evaluate the alignment matching in a θ-axis direction between the second vias 232a and 232b within the first and second memory dies 211 and 212.

When alignment matches in the X-axis direction between two second vias 232a and 232b, the two second vias 232a and 232b may completely overlap in the third direction D3.

Conversely, if the alignment does not match in the X-axis direction between the two second vias 232a and 232b, the two second vias 232a and 232b may not completely overlap in the third direction D3. Referring to FIG. 9, the second via 232b within the second memory die 212 may be shifted in the first direction D1 relative to the second via 232a within the first memory die 211. The mismatch in alignment between the two second vias 232a and 232b may result in a reduction of capacitor area, and consequently, a decrease in capacitance. FIG. 9 illustrates an example where there are multiple second vias 232a and multiple second vias 232b in the first and second directions D1 and D2. FIG. 9 is a third example diagram for explaining a method of evaluating the alignment state of the second semiconductor chip according to some embodiments of the present disclosure.

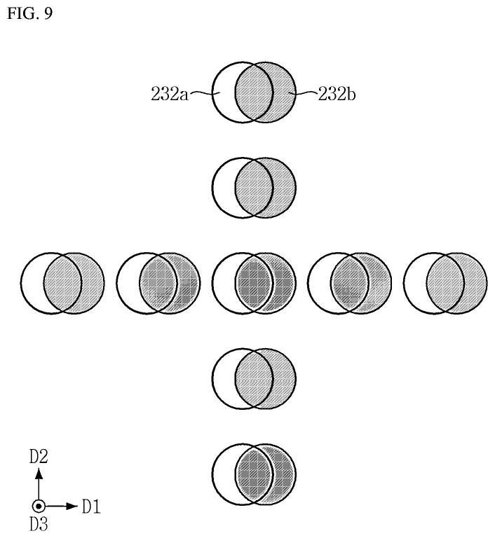

When alignment matches in the Y-axis direction between the two second vias 232a and 232b, the two second vias 232a and 232b may completely overlap in the third direction D3. Conversely, if the alignment does not match in the Y-axis direction between the two second vias 232a and 232b, the two second vias 232a and 232b may not completely overlap in the third direction D3. Referring to FIG. 10, the second via 232b within the second memory die 212 may be shifted in the second direction D2 relative to the second via 232a within the first memory die 211. The mismatch in alignment between the two second vias 232a and 232b may result in a reduction of capacitor area and, consequently, a decrease in capacitance. FIG. 10 is a fourth example diagram for explaining a method of evaluating the alignment state of a second semiconductor chip according to some embodiments of the present disclosure.

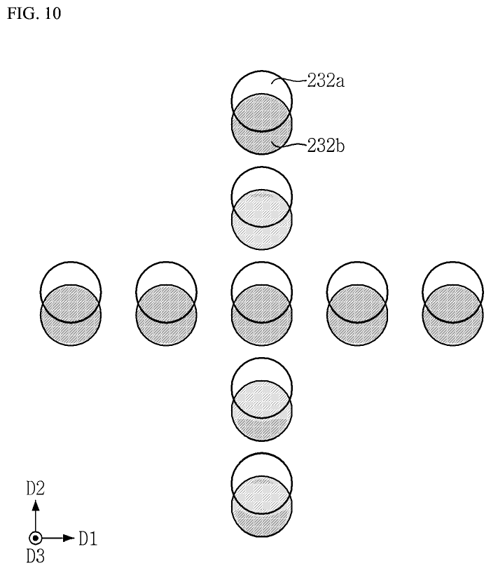

When alignment matches in the 0-axis direction between the two second vias 232a and 232b, the two second vias 232a and 232b may completely overlap in the third direction D3. Conversely, if the alignment does not match in the θ-axis direction between the two second vias 232a and 232b, the two second vias 232a and 232b do not completely overlap in the third direction D3. Referring to FIG. 11, the second via 232b within the second memory die 212 may be shifted in both the first direction D1 and the second direction D2 relative to the second via 232a within the first memory die 211. The mismatch in alignment between the two second vias 232a, 232b may result in a reduction of capacitor area and, consequently, a decrease in capacitance. FIG. 11 is a fifth example diagram for explaining the method of evaluating the alignment state of a second semiconductor chip according to some embodiments of the present disclosure.

When proceeding with a chip stack for manufacturing the semiconductor package 100 that includes an HBM, the HCB method may be used to improve signal characteristics, thermal characteristics, etc. In this case, within the memory dies 142 of the second semiconductor chip 140 that are stacked together, metal pads may be joined through TSVs. The spacing between TSV pads may be within 10 micrometers (μm), making the alignment matching between upper dies and lower dies critically important.

In the case of an alignment detection method using a vision sensor, there are limitations in analyzing a stacked structure. In the case of an electrical measurement method such as a test using direct current (DC), since each circuit is determined to be a pass or fail based on their open/short conditions, misalignments that are finely connected may not be detected, leading to detection failure and reliability issues. The present disclosure utilizes already formed TSVs and passivation films to create a plurality of capacitor structures and can thereby quantitatively detect misalignments through differences in capacitance.

The capacitor structures may be structures that include an MIM layer. The capacitor structures may be structures consisting of (metal) TSVs of an upper die, an insulator (or a passivation layer), and (metal) TSVs of a lower die. The capacitor structures with an MIM array may increase or decrease in capacitance in proportion to the differences in alignment matching of the upper and lower dies in the X-, Y-, and θ-axis directions. The capacitor structures may be formed with a passivation layer on a wafer, not requiring the addition of separate capacitors. The capacitor structures are distinct from conventional decoupling capacitors.

In the case of the TSV arrangement of an MIM structure for capacitance measurement, as the intersection area of (e.g., a width of a region of vertical overlap between) upper TSVs and lower TSVs decreases with misalignment, the electrode area and capacitance may decrease in proportion to the degree of misalignment. The MIM structure for capacitance measurement may be formed without opening backside copper pads. Accordingly, the need for an additional photolithography process can be eliminated, and simultaneous formation with a photo mask design change can be enabled.

A method of manufacturing the second semiconductor chip 140 within the semiconductor package 100 will hereinafter be described. The second semiconductor chip 140 may include an

HBM. The second semiconductor chip 140 may include the buffer die 141 and the memory dies 142. The second semiconductor chip 140 may contain a capacitor structure configured to (and thus capable of) analyzing the alignment matching of the memory dies 142. The capacitor structure may include an MIM structure.

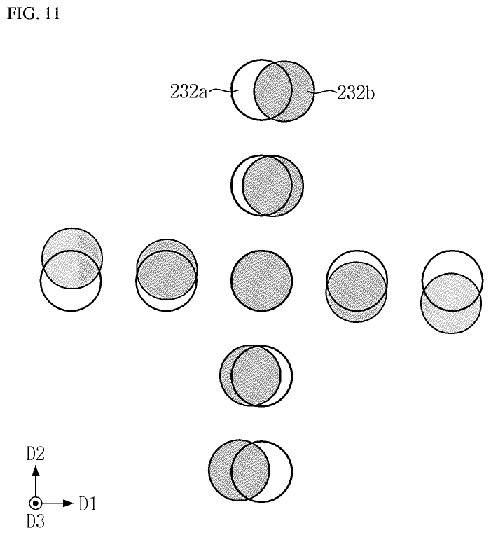

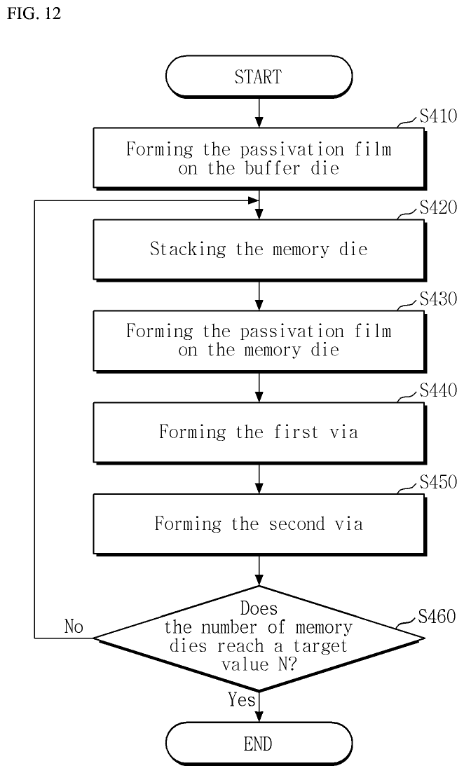

FIG. 12 is a flowchart for explaining a method of manufacturing a second semiconductor chip according to some embodiments of the present disclosure. The embodiment of FIG. 12 will hereinafter be described, taking the second semiconductor chip 140 of FIG. 5 as an example, but it should be noted that the second semiconductor chip 140 of FIG. 3 can also be manufactured in the same manner as, or a similar manner to the second semiconductor chip 140 of FIG. 5.

Referring to FIG. 12, the buffer die 141 is prepared first. The buffer die 141 may include a first via 231. Once the buffer die 141 is prepared, the first lower insulating film 221a and the first upper insulating film 221b are sequentially formed on the buffer die 141. Then, the first passivation film 221 is formed on the buffer die 141 (S410).

Thereafter, the first memory die 211 is stacked on the first passivation film 221 (S420), and the second lower insulating film 222a is formed on the first memory die 211 (S430). Thereafter, a first via 231 and a second via 232a are formed within the first memory die 211 (S440 and S450). The first via 231 may be in (e.g., may penetrate) the first lower insulating film 221a, the first upper insulating film 221b, the first memory die 211, and the second lower insulating film 222a. The first via 231 within the first memory die 211 may be electrically (and physically, such as by metal) connected to the first via 231 within the buffer die 141. The second via 232a may be in (e.g., may penetrate) the first upper insulating film 221b and the first memory die 211, but may not be in (e.g., may not penetrate) the second lower insulating film 222a.

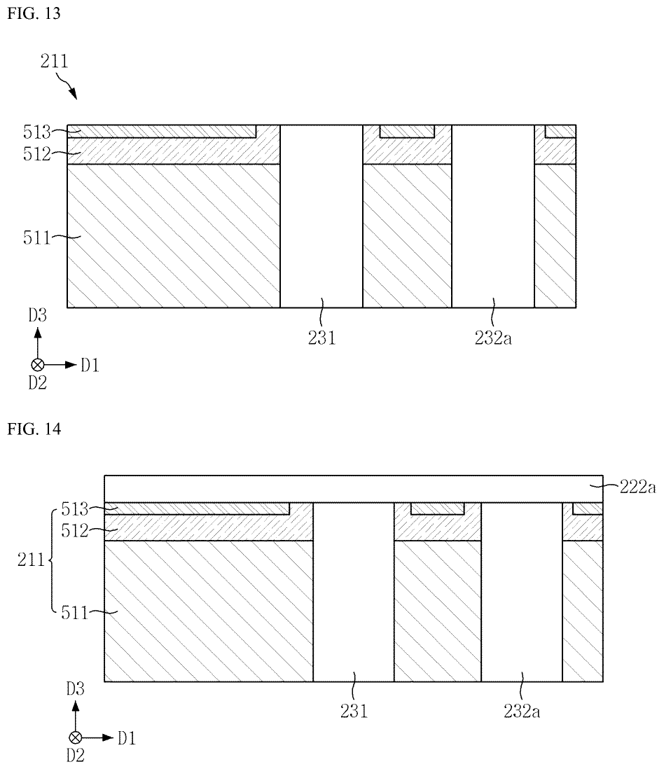

The formation of a first via 231 and a second via 232a may be performed as follows. FIGS. 13 through 20 are cross-sectional views for explaining a method of forming first and second vias within a second semiconductor chip according to some embodiments of the present disclosure.

First, a TSV reveal CMP step is performed. Referring to FIG. 13, a first via 231 and a second via 232a may be formed in the first memory die 211. The first memory die 211 may include first, second, and third portions 511, 512, and 513, but the present disclosure is not limited thereto. For example, the first, second, and third portions 511, 512, and 513 may be provided as a Si layer, a bottom oxide layer, and a SiN layer, respectively.

Thereafter, a passivation deposition step is performed. Referring to FIG. 14, the second lower insulating film 222a may be formed on the first memory die 211 through a bonding process.

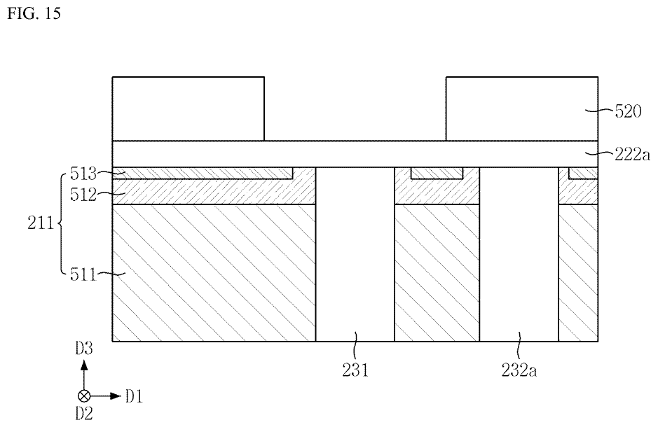

Thereafter, a pad photo step is carried out. Referring to FIG. 15, a photoresist (PR) pattern 520 may be formed on the second lower insulating film 222a.

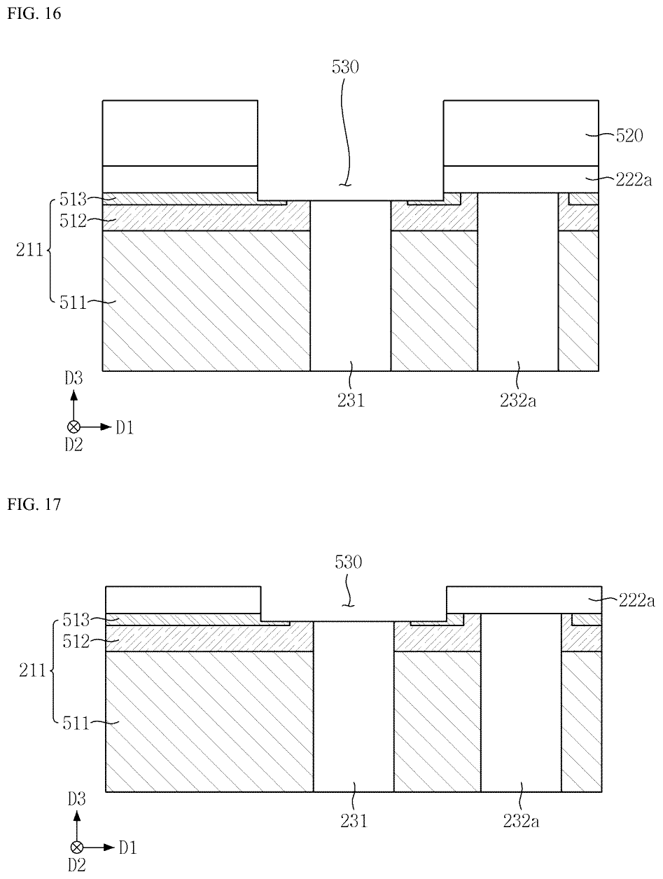

Thereafter, an oxide etch step is conducted. Referring to FIG. 16, part of the second lower insulating film 222a and part of the first memory die 211 may be etched along/through the PR pattern 520. Alternatively, only part of the second lower insulating film 222a may be etched. As a result of the oxide etch step, a groove 530 may be formed.

Thereafter, a PR strip step is performed. Referring to FIG. 17, the PR pattern 520 may be removed from above the second lower insulating film 222a.

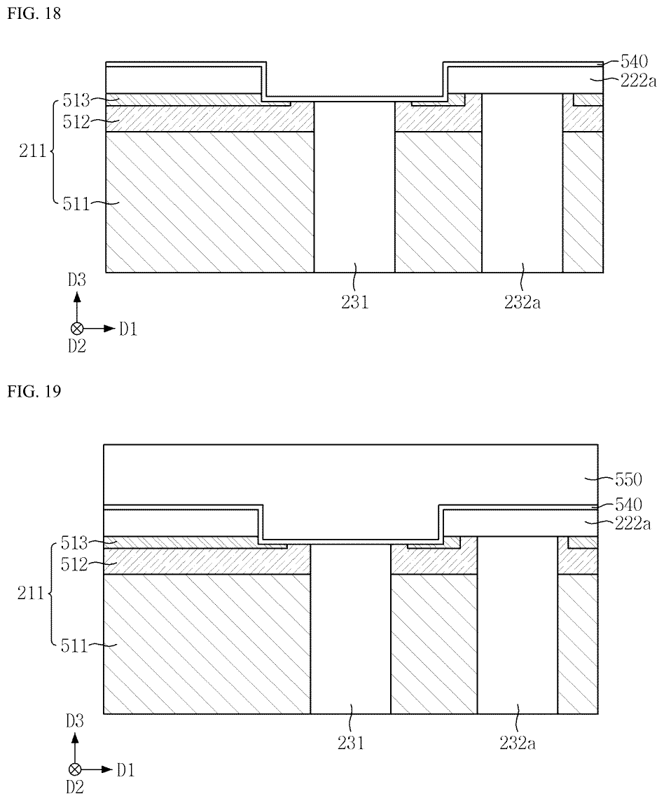

Thereafter, a seed metal deposition step is performed. Referring to FIG. 18, a seed layer 540 may be formed along the profile of the first memory die 211.

Thereafter, an electroplating step is performed. Referring to FIG. 19, a plating layer 550 may be formed on the seed layer 540. The plating layer 550 may be formed of a metal material. For example, the plating layer 550 may be formed of Cu.

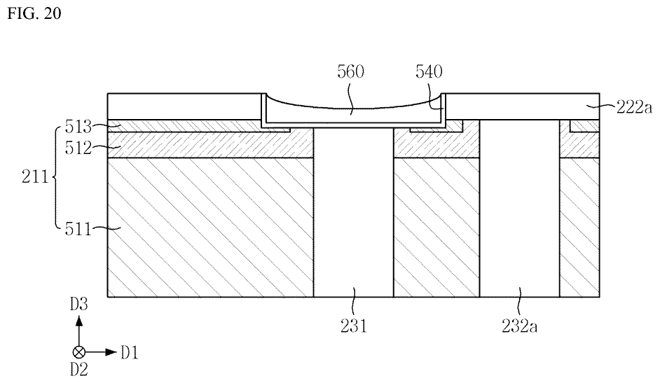

Thereafter, a CMP step is performed. Referring to FIG. 20, the plating layer 550 may be removed from above the second lower insulating film 222a, leaving a pad 560 in the groove 530.

Thereafter, referring back to FIG. 12, the second upper insulating film 222b is formed on the second lower insulating film 222a, the second memory die 212 is stacked on the second upper insulating film 222b, and then the third lower insulating film 223a is formed on the second memory die 212. Thereafter, a first via 231 and a second via 232b are formed (e.g., concurrently/simultaneously formed) within the second memory die 212. The first via 231 may be in (e.g., may penetrate) the second upper insulating film 222b, the second memory die 212, and the third lower insulating film 223a. The first via 231 within the second memory die 212 may be electrically (and physically, such as by metal) connected to the first via 231 within the first memory die 211. The second via 232b may be in (e.g., may penetrate) the second upper insulating film 222b and the second memory die 212 but may not be in (e.g., may not penetrate) the third lower insulating film 223a, which thus may separate the second via 232b from the second via 232a. The second via 232b within the second memory die 212 may not be electrically (or physically) connected to the second via 232a within the first memory die 211 by a conductive material (e.g., metal).

The formation of the first via 231 and the second via 232b within the second memory die 212 may be performed in the same manner as the formation of the first via 231 and the second via 232a within the first memory die 211.

Thereafter, the third upper insulating film 223b is formed on the third lower insulating film 223a, the third memory die 213 is stacked on the third upper insulating film 223b, and the fourth lower insulating film 224a is formed on the third memory die 213. Thereafter, a first via 231 and a second via 232c are formed within the third memory die 213. The first via 231 within the third memory die 213 may be in (e.g., may penetrate) the third upper insulating film 223b, the third memory die 213, and the fourth lower insulating film 224a. The first via 231 within the third memory die 213 may be electrically (and physically, such as by metal) connected to the first via 231 within the second memory die 212. The second via 232c may be in (e.g., may penetrate) the third upper insulating film 223b and the third memory die 213 but may not be in (e.g., may not penetrate) the fourth lower insulating film 224a. The second via 232c within the third memory die 213 may not be electrically (or physically) connected to the second via 232b within the second memory die 212 by a conductive material (e.g., metal).

The formation of the first via 231 and the second via 232c within the third memory die 213 may be performed in the same manner as the formation of the first via 231 and the second via 232a within the first memory die 211.

Thereafter, the fourth upper insulating film 224b is formed on the fourth lower insulating film 224a, and the fourth memory die 214 is stacked on the fourth upper insulating film 224b. Thereafter, a first via 231 and a second via 232d are formed within the fourth memory die 214. The first via 231 and the second via 232d may be in (e.g., may penetrate) the fourth upper insulating film 224b and the fourth memory die 214. The first via 231 within the fourth memory die 214 may be electrically (and physically, such as by metal) connected to the first via 231 within the third memory die 213. The second via 232d within the fourth memory die 214 may not be electrically (or physically) connected to the second via 232c within the third memory die 213 by a conductive material (e.g., metal).

The formation of the first via 231 and the second via 232d within the fourth memory die 214 may be performed in the same manner as the formation of the first via 231 and the second via 232a within the first memory die 211.

The second semiconductor chip 140 has been described so far as including four memory dies, i.e., the first, second, third, and fourth memory dies 211, 212, 213, and 214. However, the number of memory dies 142 included in the second semiconductor chip 140 may vary if necessary. The stacking of a plurality of memory dies 142 on the buffer die 141 may be repeated until the number of stacked memory dies 142 reaches a target value N (where N is a natural number) (S460).

Embodiments of the present disclosure have been described above with reference to the accompanying drawings, but the present disclosure is not limited thereto and may be implemented in various different forms. It will be understood that the present disclosure can be implemented in other specific forms without changing the scope of the present disclosure.

Therefore, it should be understood that the embodiments set forth herein are illustrative in all respects and not limiting.

1. A semiconductor package comprising:
a package substrate;
a first semiconductor chip mounted on the package substrate; and
a second semiconductor chip mounted on the package substrate and spaced apart from the first semiconductor chip,
wherein the second semiconductor chip includes:
a buffer die;
a first passivation film on the buffer die;
a first memory die stacked on the first passivation film;
a second passivation film on the first memory die;
a second memory die stacked on the second passivation film;
first vias in the buffer die, the first passivation film, the first memory die, the second passivation film, and the second memory die; and
second vias in the first memory die and the second memory die, respectively, and
wherein the second vias are configured to indicate an alignment between the first memory die and the second memory die.

2. The semiconductor package of claim 1, wherein the second vias are not in the second passivation film.

3. The semiconductor package of claim 1,
wherein the second vias include a conductive material, and
wherein the second passivation film includes an insulating material.

4. The semiconductor package of claim 3, wherein the alignment between the first memory die and the second memory die corresponds to a capacitance that is based on the second vias.

5. The semiconductor package of claim 4,
wherein the second via in the first memory die is electrically connected to a first capacitor,
wherein the second via in the second memory die is electrically connected to a second capacitor, and
wherein the first and second capacitors are configured to measure the capacitance.

6. The semiconductor package of claim 4, wherein the capacitance is based on a region of overlap between the second via in the first memory die and the second via in the second memory die.

7. The semiconductor package of claim 4, wherein a value of the capacitance indicates the alignment.

8. The semiconductor package of claim 1,
wherein the second passivation film includes a second lower insulating film on the first memory die and a second upper insulating film on the second lower insulating film, and
wherein the second via in the second memory die is in the second upper insulating film.

9. The semiconductor package of claim 8, wherein the second vias are not in the second lower insulating film.

10. The semiconductor package of claim 8,
wherein the second lower insulating film includes a first element and a second element,
wherein the second upper insulating film includes the first element and a third element, and
wherein the third element is a different material from the second element.

11. The semiconductor package of claim 8, wherein the first via in the first passivation film has a different width from the second via in the second upper insulating film.

12. The semiconductor package of claim 11, wherein the first via in the first passivation film has a larger width than the second via in the second upper insulating film.

13-19. (canceled)

20. A semiconductor package comprising:
a package substrate;
a first semiconductor chip mounted on the package substrate; and
a second semiconductor chip mounted on the package substrate and spaced apart from the first semiconductor chip,
wherein the second semiconductor chip includes a buffer die, a first passivation film on the buffer die, a first memory die stacked on the first passivation film, a second passivation film on the first memory die, a second memory die stacked on the second passivation film, first vias in the buffer die, the first passivation film, the first memory die, the second passivation film, and the second memory die, and second vias in the first memory die and the second memory die,
wherein the second passivation film includes a second lower insulating film on the first memory die and a second upper insulating film on the second lower insulating film, and
wherein the second vias are in the second upper insulating film and are not in the second lower insulating film,
wherein the second vias include a conductive material, and the second passivation film includes an insulating material,
wherein the second via in the first memory die is electrically connected to a first capacitor,
wherein the second via in the second memory die is electrically connected to a second capacitor, and
wherein a capacitance that corresponds to the first and second capacitors corresponds to an alignment between the first memory die and the second memory die.

21. A semiconductor package comprising:
a package substrate; and
a first semiconductor chip and a second semiconductor chip that are on the package substrate,
wherein the second semiconductor chip comprises:
a first memory die;
a second memory die that is on the first memory die;
a passivation film that is between the first memory die and the second memory die;
a first via that extends through the passivation film and the second memory die;
a second via that is in the first memory die; and
a third via that is in the second memory die,
wherein a lower surface of the third via overlaps an upper surface of the second via, and
wherein the passivation film is between the lower surface of the third via and the upper surface of the second via.

22. The semiconductor package of claim 21,
wherein the passivation film comprises an upper layer and a lower layer, and
wherein the second via and the third via are not in the lower layer.

23. The semiconductor package of claim 22, wherein the third via is in the upper layer.

24. The semiconductor package of claim 23, wherein a portion of the third via that is in the upper layer is narrower than a portion of the first via that is in the passivation film.

25. The semiconductor package of claim 24, wherein the portion of the first via is wider than another portion of the first via that is in the first memory die.

26. The semiconductor package of claim 21,
wherein the first via, the second via, and the third via include a conductive material,
wherein the passivation film includes an insulating material,
wherein the second via, the passivation film, and the third via collectively provide a metal insulator metal (MIM) structure, and
wherein a capacitance corresponding to the MIM structure is based on an amount of overlap between the second via and the third via.

27. The semiconductor package of claim 21, wherein the first via is part of a via structure that extends through the passivation film and the second memory die.
